(19) United States
(12) Patent Application Publication
(10) Pub. No.: US 2012/0196049 A1
(43) Pub. Date: Aug. 2, 2012

(54) MANUFACTURING METHOD OF MAGNETIC RECORDING MEDIUM

(75) Inventors: Shuuhei Azuma, Tokyo (JP); Keiichi Kajita, Tokyo (JP); Takashi Morikawa, Tokyo (JP)

(73) Assignee: WESTERN MEDIA (SINGAPORE) PTE. LTE., Lake Forest, CA (US)

(21) Appl. No.: 13/381,561

(22) PCT Filed: May 28, 2010
(86) PCT No.: PCT/JP2010/059127

§ 371 Date: Mar. 23, 2012

(30) Foreign Application Priority Data
Jun. 30, 2009 (JP) 2009-154722

(51) Int. Cl. G11B 5/85; C23C 16/56

(52) U.S. Cl. 427/535; 427/127

(57) ABSTRACT

A manufacturing method of a magnetic recording medium provided with a protective layer excellent in corrosion resistance, mechanical durability, adhesion with a lubrication layer, and floating stability of a head even if the film thickness is reduced is provided. This is a manufacturing method of a magnetic recording medium in which at least a magnetic layer, a carbon protective layer, and a lubrication layer are sequentially provided on a substrate, and said carbon protective layer is provided with a lower layer formed on the magnetic layer side and an upper layer formed on the lubrication layer side. The lower layer is formed by a chemical vapor deposition (CVD) method using hydrocarbon gas and then, the upper layer is formed by using mixed gas of hydrocarbon gas and nitrogen gas and then, treatment which nitridizes the surface of the upper layer is applied.

### TECHNICAL FIELD

The present invention relates to a manufacturing method of a magnetic recording medium (magnetic disk) to be mounted on a magnetic disk device such as a hard-disk drive (hereinafter abbreviated as HDD).

### BACKGROUND ART

With the recent trend to higher-capacity information processing, various information recording technologies have been developed. Particularly, a surface recording density of an HDD using the magnetic recording technology has continuously increased by the rate of approximately 100% a year. In recent years, an information recording capacity exceeding 250 G bytes per disk is required for a magnetic disk having a diameter of 2.5 inches used in HDD or the like, and in order to meet such demand, realization of an information recording density exceeding 400 Gbits per 1 square inch is in demand. In order to achieve the high recording density in a magnetic disk used in an HDD or the like, magnetic crystal grains constituting a magnetic recording layer handling recording of an information signal need to be refined, and its layer thickness needs to be reduced at the same time. However, in the case of a prior-art magnetic disk of an in-plane magnetic recording method (also referred to as longitudinal magnetic recording method or horizontal magnetic recording method), as the result of development of the refining of the magnetic crystal grains, a thermal fluctuation phenomenon in which thermal stability of the recording signal is damaged by a superparamagnetic phenomenon and the recording signal is lost begins to occur, which makes an obstructive factor to higher recording density of a magnetic disk.

In order to solve this obstructive factor, a magnetic recording medium for a perpendicular magnetic recording method has become the main stream in recent years. In the case of the perpendicular magnetic recording method, unlike the in-plane magnetic recording method, a magnetization easy axis of a magnetic recording layer is adjusted to be oriented in the perpendicular direction with respect to a substrate surface. As compared with the in-plane recording method, the perpendicular magnetic recording method can suppress the thermal fluctuation phenomenon, and this is suitable for higher recording density. This type of perpendicular magnetic recording mediums include a so-called two-layer type perpendicular magnetic recording disk provided with a soft magnetic underlayer made of a soft magnetic body on a substrate and a perpendicular magnetic recording layer made of a hard magnetic body as described in Japanese Unexamined Patent Application Publication No. 2002-74648, for example.

In the prior-art magnetic disks, with a trend to a lower floating amount of the magnetic head, it has become likely that the magnetic head is brought into contact with the surface of a magnetic recording medium due to an external impact or disturbance in flying. Thus, in order to ensure durability of the magnetic disk when the magnetic head collides with the magnetic recording medium, a protective layer is provided on a magnetic recording layer formed on a substrate. Since the protective layer requires strength and chemical durability in order to maintain excellent abrasion resistance and corrosion resistance even in a thin film, diamond-like carbon having low friction, high strength, and high chemical stability is preferably used. With regard to the prior-art protective layer, a diamond-like carbon protective layer is formed by using a CVD method by hydrocarbon gas, a sputtering method and/or the like on the magnetic recording medium. The film thickness of the prior-art protective layer needs approximately 5 to 10 nm.

Further on the protective layer, in order to protect the protective layer and the magnetic head in the case of the collision of the magnetic head, a lubrication layer is provided. A perfluoropolyether lubricant is used in general as the lubrication layer.

Moreover, in order to improve adhesion between the protective layer and the lubrication layer, Patent Document 1, for example, discloses a magnetic recording medium in which a surface layer of a carbon protective layer containing hydrogen by exposing the protective layer surface to nitrogen plasma is a layer containing nitrogen, for example. Furthermore, Patent Document 2 discloses a magnetic recording medium in which a carbon protective layer is composed of a hydrocarbon protective layer formed on the magnetic layer side and containing hydrogen and a nitrocarbon protective layer formed on the lubrication layer side containing nitrogen and not containing hydrogen.

### CITATION LIST

### Patent Literature

Patent Document 1: Japanese Unexamined Patent Application Publication No. 9-128732
Patent Document 2: Japanese Unexamined Patent Application Publication No. 2003-248917

### SUMMARY of Invention

### Technical Problem

As described above, the information recording density of 400 Gbit/inch² or more has been required for the recent HDD, but in order to effectively use a limited disk area, an LUL (Load Unload) type HDD has begun to be used instead of the prior-art CSS (Contact Start and Stop) method in a start/stop mechanism of the HDD. In the LUL method, when an HDD is stopped, a magnetic head is retreated onto an inclined base called a ramp located outside the magnetic disk and in a start operation, after the magnetic disk starts rotating, the magnetic head is made to slide from the ramp onto the magnetic disk, floated and flown for recording and reproduction. In a stop operation, the magnetic head is retreated to the ramp outside the magnetic disk and then, the rotation of the magnetic disk is stopped. This series of operations are called LUL operations. In a magnetic disk to be mounted on the LUL-method HDD, a contact sliding region (CSS region) with the magnetic head as in the CSS method does not have to be provided, and thus, a recording and reproduction area can be expanded, which is preferable for a higher information capacity.

In order to improve the information recording density under these circumstances, a spacing loss needs to be reduced as much as possible by reducing a floating amount of the magnetic head. In order to achieve the information recording density of 400 Gbits or more per 1 square inch, the floating amount of the magnetic head needs to be at least 5 nm or less. In the LUL method, unlike the CSS method, a projection-and-recess shape for the CSS does not have to be provided on the magnetic disk surface, and the magnetic disk surface can be extremely smoothened. Thus, in the magnetic disk to be mounted on the LUL method HDD, the magnetic-head floating amount can be further lowered as compared with the CSS method, and a higher S/N ratio of the recording signal can be realized, and contribution can be made to a higher recording capacity of a magnetic disk device, which is an advantage.

Due to the further decrease of the magnetic-head floating amount promoted by recent introduction of the LUL method, a stable operation of the magnetic disk even with an extremely low floating amount not more than 5 nm is in demand at the present. Particularly, as described above, the recording method of the magnetic disk has been changing from the in-plane magnetic recording method to the perpendicular magnetic recording method, and an increase in the capacity of a magnetic disk and a decrease in a flying height involved with that are in strong demand. Moreover, in order to reduce the magnetic spacing as much as possible for further improvement of the recording density, reduction of the film thickness of the protective layer and the like present between the magnetic layer and the magnetic head is an indispensable object.

Also, in recent years, the magnetic disk devices are widely used not only as a storage device of a conventional personal computer, but also in mobile applications including a mobile phone, a car-navigation system and the like, and due to diversification of use applications, environmental resistances required for the magnetic disk has become extremely severe. Therefore, in view of these situations, further improvement of stability of the magnetic disk, durability and the like is more imminent than ever.

If the protective layer is simply made into a thin film by using the prior-art CVD method or sputtering method, durability such as sliding resistance (mechanical strength), corrosion resistance and the like of the protective layer is deteriorated. Regarding the film of a carbon protective layer formed by the plasma CVD method, for example, its film quality can be easily changed by process parameters including gas pressure, gas flow rate, applied bias, and input power, but the corrosion resistance and the mechanical strength is in a relationship of trade-off, and it has been technically difficult to realize the both at the same time. Thus, in order to provide a function as the protective layer, the film thickness of the protective layer needs to be increased so that the weakest characteristic meets the required quality. However, if the film thickness of the protective layer is increased, reduction of the magnetic spacing cannot be realized, and achievement of higher recording density becomes difficult.

Particularly, if surface treatment by nitrogen plasma or the like is applied to the protective layer in order to improve adhesion between the protective layer and the lubrication layer, high energy atoms which are ionized by plasma are shot to the protective layer, and lowering of strength, density, and precision and deterioration of abrasion resistance and corrosion resistance of the protective layer involved with that shot has been considered as problems. As described above, further reduction of the film thickness of the protective layer has been in demand, and then, the thickness of the protective layer becomes close to the shot depth (intrusion depth) of the atoms by the surface treatment, and the abrasion resistance and corrosion resistance are further deteriorated by that. Moreover, according to the examination by the inventors, it was found out that if the film thickness of the protective layer becomes thinner than 4 nm, floating stability of the head is rapidly deteriorated. Here, by lowering the plasma producing power, the atom-shot depth can be decreased, but since a nitridization amount on the surface of the protective layer is decreased, adhesion with the lubrication layer is deteriorated. Therefore, in order to ensure sufficient adhesion between the protective layer and the lubrication layer, it has been indispensable to perform surface treatment by plasma of nitrogen or the like by raising the plasma producing power to some degree.

Moreover, in order to improve the adhesion between the protective layer and the lubrication layer, in a method of forming a carbon nitride protective layer containing nitrogen on the lubrication layer side by using the prior-art CVD method or sputtering method as disclosed in Patent Document 2, the lowering of strength, density, and precision of the protective layer as in the surface treatment by the nitrogen plasma can be avoided, but particularly if the film thickness of the protective layer is reduced, it is difficult to sufficiently increase the nitridization amount on the protective layer surface even if a thin film layer containing nitrogen is formed on the surface side of the protective layer. Thus, the adhesion with the lubrication layer is insufficient, and pickup of lubricant (a phenomenon in which the lubricant transfers to the head side) can easily occur.

Particularly, in recent years, regarding a magnetic head, reduction of spacing has been rapidly promoted through introduction of the DFH (Dynamic Flying Height) technology, in which a magnetic-pole tip is thermally expanded by electrifying and generating heat in a thin-film resistance body provided in the element. Thus, development of a medium which satisfies a back-off margin of a DFH element at 2 nm or less is needed. As described above, realization of a magnetic recording medium having durability and high reliability is in demand under the circumstances of lower floating amount of the magnetic head and reduction of the magnetic spacing involved with the recent higher recording density.

Furthermore, regarding the next-generation magnetic recording medium whose surface recording density exceeds 500 Gbits per 1 square inch, discrete track media in which influences such as side fringe between adjacent track bits are reduced (hereinafter referred to as DTR media) and bit patterned media (hereinafter referred to as BPM) by magnetically separating the data tracks and the bits from each other have a high degree of expectation, and realization of the magnetic recording medium having high durability and high reliability is in demand as such medium for the next-generation media.

The present invention was made in view of the above-described prior-art problems and has an object to provide a manufacturing method of a magnetic recording medium provided with a protective layer excellent in corrosion resistance, mechanical durability, adhesion with the lubrication layer, and floating stability of the head even if the film thickness is reduced.

### Solution to Problem

The inventor has found out, as the result of keen examination in order to solve the above problems, that first by forming a carbon lower layer by the CVD method by using hydrocarbon gas, and then, after a carbon upper layer is formed by using mixed gas of the hydrocarbon gas and nitrogen gas, by applying nitridization treatment by nitrogen plasma or the like on the surface of the upper layer, the shot depth of atoms caused by plasma irradiation can be made smaller (shallower) and even if the film thickness of the entire protective layer is reduced, only the uppermost surface layer can be nitridized and the nitridization amount of the uppermost surface layer can be improved, whereby the above problems can be solved, and has completed the present invention.

That is, the present invention has the following configuration:

(Composition 1)

A manufacturing method of a magnetic recording medium in which at least a magnetic layer, a carbon protective layer, and a lubrication layer are sequentially provided on a substrate, characterized in that the carbon protective layer is provided with a lower layer formed on the magnetic layer side and an upper layer formed on the lubrication layer side, and the carbon protective layer is formed by forming the lower layer by a chemical vapor deposition (CVD) method by using hydrocarbon gas and by forming the upper layer by using mixed gas of hydrocarbon gas and nitrogen gas and then, by applying treatment to nitridize the surface of the upper layer.

(Composition 2)

The manufacturing method of a magnetic recording medium described in the composition 1, characterized in that the treatment of nitridizing the surface of the upper layer is performed by exposing the surface to nitrogen plasma.

(Composition 3)

The manufacturing method of a magnetic recording medium described in the composition 1 or 2, characterized in that the film thickness of the carbon protective layer is 4 nm or less.

(Composition 4)

The manufacturing method of a magnetic recording medium described in any of the compositions 1 to 3, characterized in that a ratio in the film thickness of the lower layer to the upper layer is within a range of 9:1 to 4:1.

(Composition 5)

The manufacturing method of a magnetic recording medium described in any of the compositions 1 to 4, characterized in that the lower layer is formed by at least two-step film formation.

(Composition 6)

The manufacturing method of a magnetic recording medium described in the composition 5, characterized in that the lower layer is formed by at least two-step film formation by changing a gas pressure in a chamber in the middle of the formation.

(Composition 7)

The manufacturing method of a magnetic recording medium described in the composition 5 or 6, characterized in that the lower layer is formed by at least two-step film formation by changing applied bias in the middle.

(Composition 8)

The manufacturing method of a magnetic recording medium described in any of the compositions 1 to 7, characterized in that the upper layer is formed by the CVD method.

(Composition 9)

The manufacturing method of a magnetic recording medium described in any of the compositions 1 to 8, characterized in that the lubrication layer contains a lubricant having at least three or more hydroxyl groups in one molecule.

(Composition 10)

The manufacturing method of a magnetic recording medium described in any of the compositions 1 to 9, characterized in that the magnetic recording medium is mounted on a magnetic disk device whose start/stop mechanism is of a load-unload type and used with a head floating amount of 5 nm or less.

(Composition 11)

The manufacturing method of a magnetic recording medium described in the composition 10, characterized in that a DFH head which thermally expands a magnetic-pole tip of a recording/reproducing element is used.

(Composition 12)

The manufacturing method of a magnetic recording medium described in any of the compositions 1 to 11, characterized in that the magnetic recording medium is a medium for discrete track media or a medium for bit patterned media.

### Advantageous Effects of Invention

According to the present invention, a manufacturing method of a magnetic recording medium such as a magnetic disk or the like provided with a protective layer excellent in corrosion resistance, mechanical durability, adhesion with a lubrication layer, and floating stability of a head even if the film thickness of the protective layer is reduced can be provided. As a result, further reduction of magnetic spacing can be realized and moreover, even under the circumstance of a low floating amount of a magnetic head involved with the recent rapidly increasing recording density and extremely severe environmental resistance involved with diversified applications, a magnetic recording medium having high durability and high reliability can be obtained.

### BRIEF DESCRIPTION OF DRAWINGS

FIG. 1 is a sectional diagram illustrating an embodiment of a layered configuration of a perpendicular magnetic recording medium according to the present invention.

FIG. 2 is a diagram illustrating comparison between the present invention and the prior-art magnetic recording medium of a relationship between nitrogen plasma generation power and a ratio of presence (N/C) of nitrogen atoms (N) to carbon atoms (C) in a protective layer.

### DESCRIPTION OF EMBODIMENTS

The present invention will be described below in detail by using an embodiment.

First, an outline of a magnetic recording medium manufactured by the present invention or particularly of a perpendicular magnetic recording medium suitable for higher recording density will be described.

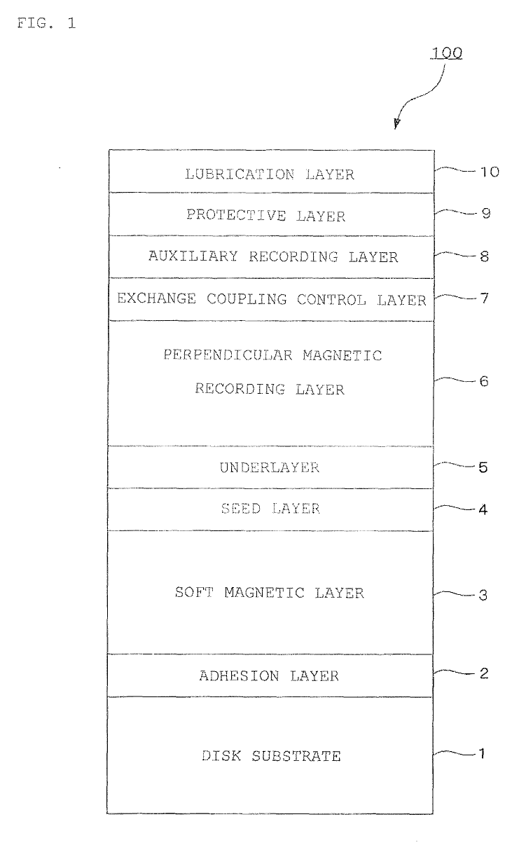

FIG. 1 is a sectional diagram illustrating an embodiment of a layered configuration of a perpendicular magnetic recording medium according to the present invention. As illustrated in FIG. 1, specifically, as an embodiment 100 of the layered configuration of the perpendicular magnetic recording medium according to the present invention, an adhesion layer 2, a soft magnetic layer 3, a seed layer 4, an underlayer 5, a magnetic recording layer (perpendicular magnetic recording layer) 6, an exchange coupling control layer 7, an auxiliary recording layer 8, a protective layer 9, and a lubrication layer 10 are laminated on a disk substrate 1 from the side closer to the substrate, for example.

Aluminosilicate glass, aluminoborosilicate glass, soda-lime glass and the like can be cited as glass for the above-described disk substrate 1, and aluminosilicate glass among them is suitable. Amorphous glass and crystallized glass can be also used. Chemically reinforced glass is high in rigidity and preferable. In the present invention, surface roughness on the major surface of the substrate is preferably 3 nm or less in Rmax and 0.3 nm or less in Ra.

The soft magnetic layer 3 which favorably adjusts magnetic circuit of the perpendicular magnetic recording layer is preferably provided on the substrate 1. Such soft magnetic layer is preferably configured so as to include an AFC (Antiferro-magnetic exchange coupling) by interposing a non-magnetic spacer layer between a first soft magnetic layer and a second soft magnetic layer. As a result, a magnetization direction of the first soft magnetic layer and the second soft magnetic layer can be aligned in anti-parallel with a high accuracy, and a noise generated from the soft magnetic layer can be reduced. Specifically, the compositions of the first soft magnetic layer and the second soft magnetic layer can be, for example, CoTaZr (cobalt-tantalum-zirconium), CoFeTaZr (cobalt-iron-tantalum-zirconium), CoFeTaZrAlCr (cobalt-iron-tantalum-zirconium-aluminum-chromium) or CoFeNiTaZr (cobalt-iron-nickel-tantalum-zirconium). The composition of the spacer layer can be, for example, Ru (ruthenium).

The film thickness of the soft magnetic layer depends on its structure and the structure and characteristics of a magnetic head but is preferably 15 to 100 nm as a whole. The film thickness of each of the upper and lower layers can be made somewhat different for optimization of recording and reproduction but is substantially the same preferably.

Moreover, the adhesion layer 2 is preferably formed between the substrate 1 and the soft magnetic layer 3. The adhesion between the substrate and the soft magnetic layer can be improved, and separation of the soft magnetic layer can be prevented by forming the adhesion layer. A material containing Ti, for example, can be used as the material for the adhesion layer.

Moreover, the seed layer 4 is used for orientation and controlling crystallization of the underlayer 5. This layer is not particularly necessary if all the layers of the medium are film-formed continuously, but crystalline growth can be deteriorated depending on chemistry between the soft magnetic layer and the underlayer. The deterioration of the crystalline growth of the underlayer can be prevented by using the seed layer. The film thickness of the seed layer is preferably the minimum required for control of crystalline growth of the underlayer. If the layer is too thick, it might deteriorate writing capacity of a signal.

The underlayer 5 is used for suitably controlling crystalline orientation of the perpendicular magnetic recording layer 6 (the crystalline orientation is oriented in the perpendicular direction to the substrate surface), crystal grain size, and grain boundary. A single body or an alloy having a face-centered cubic (fcc) structure or a hexagonal close-packed (hcp) structure is preferable as the material for the underlayer, and Ru, Pd, Pt, Ti, and alloys containing them can be cited, but they are not limiting. In the present invention, particularly Ru or its alloy is preferably used. In the case of Ru, an action for controlling such that a crystal axis (c-axis) of a CoPt perpendicular magnetic recording layer having an hcp crystalline structure to be oriented in the perpendicular direction is high and suitable. In the case of a lamination structure by a low gas pressure process and a high gas pressure process, not only the same materials but also different types of materials can be combined.

Moreover, the perpendicular magnetic recording layer 6 preferably includes a ferromagnetic layer with a granular structure having crystal particles primarily including cobalt (Co) and a grain boundary portion primarily including Si, Ti, Cr, Co or an oxide of Si, Ti, Cr or Co.

Specifically, as the Co magnetic material constituting the ferromagnetic layer, such a material is preferable that molds an hcp crystal structure by using a target of a hard magnetic body made of CoCrPt (cobalt—chromium—platinum) containing at least one of silicon oxide (SiO₂) or titanium oxide (TiO₂), which are non-magnetic substances. Moreover, the film thickness of this ferromagnetic layer is preferably 20 nm or less, for example. Furthermore, this ferromagnetic layer may be a single layer or may be composed of a plurality of layers.

Moreover, by providing the auxiliary recording layer 8 on the perpendicular magnetic recording layer 6 through the exchange coupling control layer 7, characteristics such as improvement of reverse magnetic domain nucleation magnetic field Hn, improvement of heat-resistant fluctuation characteristics, improvement of overwriting characteristics and the like can be added to recording performances with high density and low noise. The composition of the auxiliary recording layer can be CoCrPtB, for example.

Moreover, the exchange coupling control layer 7 is preferably provided between the perpendicular magnetic recording layer 6 and the auxiliary recording layer 8. The recording/reproducing characteristics can be optimized by favorably controlling strength of exchange coupling between the perpendicular magnetic recording layer and the auxiliary recording layer by providing the exchange coupling control layer. Ru or the like is preferably used as the exchange coupling control layer, for example.

The perpendicular magnetic recording layer including the ferromagnetic layer is preferably film-formed by using the sputtering method. Particularly, the DC magnetron sputtering method is preferable since uniform film formation is possible.

Moreover, the protective layer 9 is provided on the perpendicular magnetic recording layer (on the auxiliary recording layer in this embodiment). The magnetic disk surface can be protected from the magnetic head floating and flying over the magnetic recording medium by providing the protective layer. A carbon protective layer is preferable as the material of the protective layer.

Moreover, the lubrication layer 10 is preferably further provided on the protective layer 9. Abrasion between the magnetic head and the magnetic disk can be suppressed, and durability of the magnetic disk can be improved by providing the lubrication layer. A PFPE (perfluoropolyether) compound, for example, is preferable as the material of the lubrication layer. The lubrication layer can be formed by the dip coat method, for example.

The present invention is, as described in the invention in the composition 1, a manufacturing method of a magnetic recording medium in which at least a magnetic layer, a carbon protective layer, and a lubrication layer are sequentially provided on a substrate, characterized in that the carbon protective layer is provided with a lower layer formed on the magnetic layer side and an upper layer formed on the lubrication layer side, and the carbon protective layer is formed such that, after the lower layer is formed by the chemical vapor deposition (CVD) method by using hydrocarbon gas and then, the upper layer is formed by using mixed gas of hydrocarbon gas and nitrogen gas, treatment of nitridizing the surface of the upper layer is applied.

In the present invention, the carbon protective layer is provided with a lower layer formed on the magnetic layer side and an upper layer formed on the lubrication layer side. In the carbon protective layer, the lower layer formed on the magnetic layer side is formed by the CVD method by using hydrocarbon gas. Lower hydrocarbon gas represented by ethylene gas (carbon number of approximately 1 to 5), for example, is favorably used as the hydrocarbon gas used for film formation by the CVD method. Process parameters such as gas pressure, gas flow, applied bias, input power and the like are set as appropriate. As a result, a CH layer is formed on the lower layer.

Moreover, the upper layer formed on the lubrication layer side in the carbon protective layer is formed by the CDV method, for example, by using mixed gas of hydrocarbon gas and nitrogen gas. The process parameters such as gas pressure, gas flow, applied bias, input power and the like in the chamber during film formation are set as appropriate. As a result, a CHN layer is formed in the upper layer. A mixing ratio of the hydrocarbon gas and the nitrogen gas in this case is not particularly limited in the present invention, but if an introduced amount of the nitrogen gas is too small, a nitrogen content in the CHN layer to be formed becomes relatively smaller. Thus, unless nitrogen plasma generation power is raised to some degree in the nitridization treatment which will be performed after that by using nitrogen plasma, for example, it becomes difficult to increase the nitridization amount on the upper-layer surface and sufficient adhesion with the lubrication layer cannot be obtained. If the nitrogen plasma generation power is raised, it causes a problem that a damage depth caused by shot of the nitrogen atoms becomes larger. On the other hand, if the introduced amount of the nitrogen gas to the hydrocarbon gas is too large, an increase of the nitrogen content in the CHN layer to be formed is limited. Therefore, in the film formation of the CHN layer in the upper layer, the mixing ratio of the nitrogen gas to the hydrocarbon gas is preferably within a range of approximately 1:4 to 4:1 in flow ratio (by the unit of sccm).

The film forming method of the upper layer is not limited to the CVD method, but from the viewpoint that the upper layer can be formed in the same chamber continuously after the lower layer is formed by the CVD method, the upper layer is also preferably formed by the CVD method.

Moreover, the film thickness ratio between the lower layer and the upper layer in the carbon protective layer in the present invention is preferably within a range of 9:1 to 4:1. If the film thickness of the upper layer is relatively smaller than the above range, for example, many of the shot nitrogen atoms reach the CH layer in the lower layer in the nitridization treatment by nitrogen plasma, and there is a concern that the nitrogen amount on the upper-layer surface of the protective layer which contributes to the adhesion with the lubrication layer cannot be raised. As will be described later, according to the findings of the inventors, the CHN layer in the upper layer is considered to exert an action to relax impact when the ionized high-energy nitrogen atoms are shot and as a result, to suppress the shot depth of the nitrogen atoms. If the film thickness of the upper layer is small, the action cannot be obtained easily. On the other hand, if the film thickness of the upper layer is larger than the above range, the film thickness of the CH layer in the lower layer becomes relatively small, and mechanical durability and corrosion resistance as the protective layer are lowered.

From the viewpoint of demand for thinner films, the film thickness (total film thickness) of the carbon protective layer formed by the present invention is preferably 4 nm or less. Particularly, it is preferably within a range of 2 to 4 nm. If the film thickness of the protective layer is less than 2 nm, performances as the protective layer might be lowered.

Moreover, the film thickness of the upper layer in the protective layer is preferably within a range of 0.2 to 0.8 nm. If the film thickness of the upper layer is smaller than the above range, the action to relax impact when the ionized high-energy nitrogen atoms are shot and to suppress the shot depth of the nitrogen atoms cannot be obtained easily. On the other hand, if the film thickness of the upper layer is larger than the above range, from the viewpoint of thinning of the entire protective layer, the film thickness of the lower layer becomes relatively small, and mechanical durability and corrosion resistance are lowered.

Moreover, the film thickness of the lower layer in the protective layer is preferably within a range of 1.6 to 3.6 nm. If the film thickness fo the lower layer is smaller than the above range, mechanical durability and corrosion resistance of the protective layer are deteriorated. On the other hand, if the film thickness of the lower layer is larger than the above range, it is not preferable from the viewpoint of reduction of the film thickness of the protective layer.

In the present invention, the film thickness of the protective layer (referring to the total film thickness and the film thickness of each of the upper layer and the lower layer) is assumed to be the film thickness measured by transmission electron microscope (TEM).

Exposure to (or irradiation with) nitrogen plasma is preferable as the treatment for nitridizing the surface of the upper layer. The surface layer of the upper layer is nitridized by exposing the upper layer to the nitrogen plasma, and the nitridization amount of the surface of the upper layer can be improved to such a degree that sufficient adhesion can be obtained with the lubrication layer. In the present invention, plasma generation power is preferably set within a range of 25 to 75 W. In the prier-art technology, the plasma generation power needs to be set to approximately 100 W at the minimum in order to improve the nitridization amount on the surface of the protective layer to such a degree that sufficient adhesion with the lubrication layer can be obtained. However, in the present invention, the nitridization amount on the surface of the protective layer can be improved to such a degree that sufficient adhesion with the lubrication layer can be obtained with power lower than before.

Moreover, in the present invention, the CH layer of the lower layer is more preferably formed of two-step film formation. In this case, formation at least by means of the two-step film formation by changing the gas pressure in the chamber in the middle of the formation is preferable. Furthermore, formation can be performed at least by means of the two-step film formation by changing substrate applied bias during film formation in the middle of the formation. Furthermore, formation can be performed at least by means of the two-step film formation by changing the gas pressure in the chamber and the applied bias in the middle.

In the present invention, it is particularly preferable that the CH layer of the lower layer is formed by means of the two-step film formation in which the film is first formed by a high gas pressure and then, the gas pressure is changed to a low gas pressure in the middle. Such two-step film formation reduces damage to the magnetic recording layer of the lower layer and as compared with the continuous film formation without changing the gas pressure or the like in the middle of the formation, particularly favorable magnetic characteristics and recording/reproducing characteristics can be obtained. The high gas pressure in this case is preferably set within a range of 4.0 to 2.0 Pa and the low gas pressure within a range of 1.5 to 0.5 Pa. When the gas pressure in the chamber is to be changed, standby time during which the applied bias of the substrate is set to 0 (zero) V and film formation is not performed may be provided until pressure fluctuation is settled and the inside of the chamber is stabilized. A film thickness ratio between the layer to be film-formed first by the high gas pressure (high gas pressure layer) and the layer to be film-formed by the low gas pressure from the middle (low gas pressure layer) is preferably set to approximately 1:3 to 1:5. If the film thickness of the layer to be formed by the high gas pressure falls below the above range, damage to the magnetic recording layer becomes extreme, while if the film thickness exceeds the above range, the film thickness of the layer to be formed by the low gas pressure excellent in precision becomes relatively small, and sufficient mechanical durability as the protective film cannot be ensured.

Moreover, if the applied bias is to be changed instead of the change of the above-described gas pressure or along with the change of the gas pressure, the two-step film formation is preferable in which first, film formation is performed by a low bias and then, the bias is changed to a high bias in the middle of the formation. The low bias in this case is preferably set within a range of 50 to 300 V and the high bias within a range of 300 to 400 V.

The lubrication layer formed on the carbon protective layer in the present invention preferably contains a perfluoropolyether lubricant having at least three or more hydroxyl groups per molecule. According to the present invention, only the outermost surface (surface layer) of the carbon protective layer is nitridized and an adhesion point (active point) with the lubrication layer can be sufficiently formed in the surface layer of the lubrication layer side of the protective layer, which contributes to adhesion with the lubrication layer. Since a polar group such as a hydroxyl group is present in the molecule of the lubricant, favorable adhesion of the lubricant to the protective layer can be obtained by means of interaction between the carbon protective layer and the hydroxyl group in the lubricant molecule. And thus, particularly, a perfluoropolyether lubricant having at least three or more hydroxyl groups per molecule is preferably used.

As described above, according to the present invention, even if the film thickness is reduced, a carbon protective layer provided with corrosion resistance, mechanical durability, adhesion with the lubrication layer, and floating stability of the head can be formed, and further reduction of magnetic spacing can be realized. Moreover, even under the circumstance of an extremely low floating amount (5 nm or less) of a magnetic head involved with the recent rapidly increasing recording density and extremely severe environmental resistance involved with diversified applications, a magnetic recording medium having high durability and high reliability can be obtained.

The inventors have also examined the reasons why favorable corrosion resistance, mechanical durability, adhesion with the lubrication layer, and floating stability of the head can be obtained even if the film thickness of the protective layer is reduced and inferred as follows:

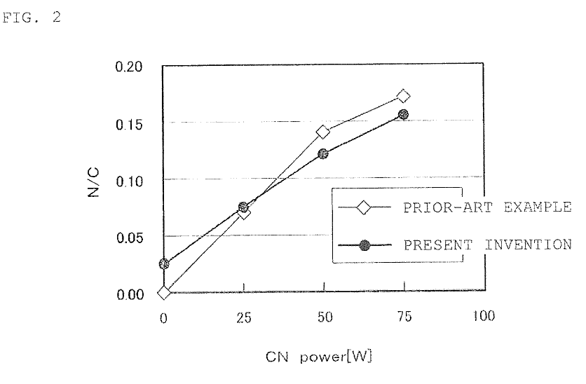

FIG. 2 is a diagram illustrating comparison relationship between nitrogen plasma generation power and a ratio of presence (N/C) of nitrogen atoms (N) to carbon atoms (C) in the protective layer. The vertical axis in FIG. 2 indicates the ratio of presence (N/C) of nitrogen atoms (N) to carbon atoms (C) in the protective layer measured by X-ray photoelectron spectroscopy (XPS) in a ratio of atoms.

According to FIG. 2, an increase rate (inclination) of the N/C ratio to the nitrogen plasma generation power in the present invention is smaller than the prior-art example of nitridization treatment in which the surface of the CH layer formed by the CVD method is exposed to nitrogen plasma. Moreover, in the present invention, the N/C when the plasma generation power is 0 (zero) W reflects N content in the CHN layer of the upper layer.

According to the findings of the inventors, when the protective layer is exposed to nitrogen plasma and ionized high-energy nitrogen atoms are shot, a part of N atoms (as CHN) in the CHN layer is emitted. That is, when exposed to nitrogen plasma, nitridization progresses in the CHN layer of the upper layer while the N atoms in the CHN layer are somewhat being etched. Thus, the CHN layer in the upper layer is considered to exert an action of relaxing the impact when the ionized high-energy nitrogen atoms are shot and as a result, of suppressing the shot depth (intrusion depth) of the nitrogen atoms. Moreover, in the present invention, the nitridization amount on the surface of the protective layer can be improved to such a degree that sufficient adhesion with the lubrication layer can be obtained with the plasma generation power lower than before. In short, it is possible to sufficiently nitridize only the outermost surface (surface layer) of the carbon protective layer, which contributes to adhesion with the lubrication layer, and damage caused by shot of high-energy nitrogen atoms by plasma remains only on the surface layer portion of the protective layer (the CHN layer of the upper layer), if any, and corrosion resistance or mechanical durability is not deteriorated.

As described above, according to the present invention, the film thickness of the protective layer can be reduced more than before, and moreover, favorable corrosion resistance, mechanical durability, adhesion with the lubrication layer, and floating stability of the head can be considered to be obtained.

Moreover, the magnetic recording medium of the present invention is suitable for a magnetic recording medium mounted particularly on a LUL type magnetic disk device. A stable operation of the magnetic recording medium even with a super low floating amount of 5 nm or less, for example, is in demand due to further lowering of the floating amount of the magnetic head involved with the introduction of the LUL method, and the magnetic recording medium of the present invention having high durability and reliability with the low floating amount is favorable.

Moreover, in recent years, regarding a magnetic head, reduction of spacing has been rapidly promoted through introduction of the DFH (Dynamic Flying Height) technology, in which a magnetic-pole tip is thermally expanded by electrifying and generating heat in a thin-film resistance body provided in the element. Thus, development of a medium which satisfies a back-off margin of a DFH element at 2 nm or less is needed. As described above, realization of a magnetic recording medium in the present invention having high durability high reliability is favorable under the circumstances of lower floating amount of the magnetic head and reduction of the magnetic spacing involved with the recent higher recording density.

Furthermore, regarding the next-generation magnetic recording medium whose surface recording density exceeds 500 Gbits per 1 square inch, DTR media and BPM in which influences of side fringe or the like between adjacent track bits are reduced by magnetically separating the data tracks and bits from each other have a high degree of expectation, and the magnetic recording medium in the present invention having high durability and high reliability is favorable for the medium for the next-generation media.

### EXAMPLE

The present invention will be described below in more detail by means of examples.

### Example 1

Amorphous aluminosilicate glass was molded into a disk shape using direct press, and a glass disk was fabricated. This glass disk was sequentially subjected to grinding, polishing, and chemical strengthening, and a smooth non-magnetic glass substrate made of a chemically strengthened glass disk was obtained. The disk diameter is 65 mm. The surface roughness of the major surface of this glass substrate was measured by AFM (atomic force microscope), and the surface shape was smooth with Rmax at 2.18 nm and Ra at 0.18 nm. Rmax and Ra comply with Japanese Industrial Standards (JIS).

Subsequently, films of an adhesion layer, a soft magnetic layer, a seed layer, an underlay first layer, an underlay second layer, a perpendicular magnetic recording layer, an exchange coupling control layer and an auxiliary recording layer are sequentially formed on the glass substrate by using a leaf-type static opposing sputtering device with a DC magnetron sputtering method.

The following numerical values in the description of each material indicate compositions.

First, a 10-nm film of Cr-45Ti layer was formed as an adhesion layer.

Then, a laminated film of two layers of a soft magnetic layer antiferromagnetically exchange-coupled having a non-magnetic layer between them was formed as a soft magnetic layer. That is, a film of 25-nm 92 (60Co40Fe)-3Ta-5Zr layer was formed as a first soft magnetic layer and then, a film of a 0.5-nm Ru layer was formed as a non-magnetic layer, and moreover, a film of the 92(60Co40Fe)-3Ta-5Zr layer, the same as the first soft magnetic layer, was formed as the second soft magnetic layer having 25 nm.

Subsequently, a 5-nm film of a Ni5W layer was formed as a seed layer on the soft magnetic layer.

Subsequently, films of two layers of an Ru layer were formed as an underlayer. That is, a 12-nm film of Ru was formed at an Ar gas pressure of 0.7 Pa as the underlay first layer, and a 12-nm film of Ru was formed at an Ar gas pressure of 4.5 Pa as the underlay second layer.

Subsequently, a film of a magnetic recording layer was formed on the underlayer. First, a film of 93 (Co-20Cr-18Pt)-7Cr203 having the thickness of 2 nm was formed as a perpendicular magnetic recording layer and then, a film of 87(Co-10Cr-18Pt)-5SiO2-5TiO2-3Co0 having the thickness of 9 nm was formed on top of it. Then, a 0.3-nm film of an Ru layer was formed as an exchange-coupling control layer, and moreover, a 7-nm film of Co-18Cr-13Pt-5B was formed as an auxiliary recording layer on top of it.

Then, a protective layer was formed by using ethylene gas by the CVD method on the auxiliary recording layer. First, a gas pressure was set to 3.5 Pa while the ethylene gas flowed through the chamber at 500 sccm and bias of −400 V was applied to the substrate, and a 0.9-nm film of a CH layer was formed. At this time, a flow of the ethylene gas was changed to 150 sccm and the gas pressure in the chamber was lowered to 0.9 Pa, and a film of CH layer was continuously formed by 2.3 nm in this state.

After that, nitrogen gas was further introduced into the chamber, and while the gas pressure was set to 1.5 Pa in an atmosphere of mixed gas of the ethylene gas and nitrogen gas (flow ratio C₂H₄:N₂=250 sccm:300 sccm) and the bias of −400 V is applied to the substrate, a 0.3-nm film of a CHN layer was formed.

Subsequently, nitridization treatment in which the CHN layer on the upper layer side of the formed protective layer was exposed to nitrogen plasma was executed. At this time, the nitrogen gas was introduced so that the pressure in the chamber becomes 6 Pa, the plasma was generated by electric power at 25 W, and the CHN layer was exposed to the nitrogen plasma for 2.5 seconds.

The film thickness of each layer in the protective layer was measured by using a transmission electron microscope (TEM).

The magnetic recording medium in which layers up to the protective layer (total film thickness of 3.5 nm) were formed as above is washed and then, Fomblin Z-tetraol (product name) by Solvay Solexis, Inc., which is a perfluoropolyether (PFPE) lubricant, was subjected to molecular weight fractionation by a GPC method, and the lubricant with the molecular weight dispersion of 1.08 was applied by the dip method so as to form a 1.8-nm film of a lubrication layer of the protective layer. The lubricant has four hydroxyl groups per molecule.

After the film formation, the magnetic disk was subjected to heating treatment in a furnace at 110° C. for 60 minutes.

As described above, the magnetic disk of Example 1 was obtained.

### Example 2

In the film-forming process of the protective layer in Example 1, the protective layer was formed similarly to Example 1 except that a 0.9-nm film of the CH layer was formed at the gas pressure of 3.5 Pa and then, a 1.8-nm film of the CH layer was formed at the gas pressure of 0.9 Pa, and after that, a 0.3-nm film of the CHN layer was formed so as to have the total film thickness of the protective layer of 3 nm.

The magnetic disk was fabricated similarly to Example 1 except for that point, and the magnetic disk of Example 2 was obtained.

### Example 3

In the film-forming process of the protective layer in Example 1, the protective layer was formed similarly to Example 1 except that a 0.9-nm film of the CH layer was formed at the gas pressure of 3.5 Pa and then, a 1.9-nm film of the CH layer was formed at the gas pressure of 0.9 Pa, and after that, a 0.7-nm film of the CHN layer was formed so as to have the total film thickness of the protective layer of 3.5 nm.

The magnetic disk was fabricated similarly to Example 1 except for that point, and the magnetic disk of Example 3 was obtained.

### Example 4

A film of the protective layer was formed as follows. First, a gas pressure was set to 3.5 Pa while the ethylene gas flowed through the chamber at 500 sccm and bias of −300 V is applied to the substrate, and a 0.9-nm film of a CH layer was formed. At this time, a flow of the ethylene gas was changed to 150 sccm and the gas pressure in the chamber was lowered to 0.9 Pa, and a film of CH layer was continuously formed by 2.8 nm by changing the bias to −400 V.

After that, nitrogen gas was further introduced into the chamber similarly to Example 1, and while the gas pressure was set to 1.5 Pa in an atmosphere of mixed gas of the ethylene gas and nitrogen gas (flow ratio C₂H₄:N₂=250 sccm:300 sccm) and the bias of −400 V was applied to the substrate, a 0.3-nm film of a CHN layer was formed.

Subsequently, nitridization treatment in which the CHN layer on the upper layer side of the formed protective layer was exposed to nitrogen plasma was executed similarly to Example 1. At this time, the nitrogen gas was introduced so that the pressure in the chamber becomes 6 Pa, the plasma was generated by electric power at 25 W, and the CHN layer was exposed to the nitrogen plasma for 2.5 seconds.

The magnetic disk was fabricated similarly to Example 1 except that the protective layer was formed as above, and he magnetic disk of Example 4 was obtained.

### Example 5

The lubrication layer was formed similarly to Example 1 except that in the film forming process of the lubrication layer in Example 1, Fomblin Z-dol (product name) by Solvay Solexis, Inc., which is a perfluoropolyether (PFPE) lubricant, was subjected to molecular weight fractionation by the GPC method, and the lubricant with the molecular weight dispersion of 1.08 was applied by the dip method so as to form a 1.8-nm film of a lubrication layer. The lubricant has two hydroxyl groups per molecule.

The magnetic disk was fabricated similarly to Example 1 except for that point, and the magnetic disk of Example 5 was obtained.

### Example 6

Similarly to Example 1, films of an adhesion layer, a soft magnetic layer, a seed layer, an underlay first layer, an underlay second layer, a perpendicular magnetic recording layer, an exchange coupling control layer and an auxiliary recording layer are sequentially formed on the glass substrate by using a leaf-type static opposing sputtering device with a DC magnetron sputtering method. Then, a protective layer made of hydrogenated diamond-like carbon was formed on the auxiliary recording layer by the DC magnetron sputtering method. The film thickness of the protective layer was set to 4 nm.

Subsequently, a DTR media having a track pitch of 120 nm was manufactured by using the perpendicular magnetic recording medium fabricated as above.

First, DTR patterning was performed on the perpendicular magnetic recording medium by using the UV nano-imprint method using quartz mold. Then, a resist remaining film and a protective layer (DLC) were removed by the inductive-coupled plasma reactive ion etching method (ICP-RIE). Moreover, etching of the magnetic recording layer (perpendicular magnetic recording layer, exchange coupling control layer, and auxiliary recording layer) was performed by the ion beam etching (IBE) method. After that, a groove generated after the etching of the magnetic recording layer was filled by using the RF-sputtering method using a non-magnetic material target such as SiO₂ and NiAl. Then, after flattening by using the IBE again, the carbon protective layer and the lubrication layer similar to those in Example 1 were formed of the surface thereof, and the DTR media having a track pitch of 120 nm (magnetic disk of Example 6) was manufactured.

### Comparative Example 1

A protective layer was formed by the CVD method by using ethylene gas. That is, the ethylene gas was introduced into the chamber and while the gas pressure was set to 2 Pa and the bias of −400 V was applied to the substrate, a 3.5-nm film of the CH layer was formed.

Subsequently, nitridization treatment in which the formed protective layer (CH layer) is exposed to nitrogen plasma was executed. At this time, nitrogen gas was introduced so that the pressure in the chamber becomes 6 Pa, plasma was generated by electric power at 100 W, and the layer was exposed to the nitrogen plasma for 2.5 seconds.

The magnetic disk was fabricated similarly to Example 1 except that the protective layer was formed as above, and the magnetic disk of Comparative Example 1 was obtained.

### Comparative Example 2

A protective layer was formed by the CVD method by using ethylene gas. First, the ethylene gas was introduced into the chamber and while the gas pressure was set to 3.5 Pa and bias of −400 V was applied to the substrate, a 0.9-nm film of a CH layer was formed. After that, a flow of the ethylene gas was changed and the gas pressure in the chamber was lowered to 0.9 Pa, and a film of CH layer is continuously formed by 2.6 nm in this state.

Subsequently, nitridization treatment in which the formed protective layer (CH layer) is exposed to nitrogen plasma was executed. At this time, nitrogen gas was introduced so that the pressure in the chamber becomes 6 Pa, plasma was generated by electric power at 75 W, and the layer was exposed to the nitrogen plasma for 2.5 seconds.

The magnetic disk was fabricated similarly to Example 1 except that the protective layer was formed as above, and the magnetic disk of Comparative Example 2 was obtained.

### Comparative Example 3

A protective layer was formed by the CVD method by using ethylene gas. First, the ethylene gas was introduced into the chamber and while the gas pressure was set to 2 Pa and bias of −400 V was applied to the substrate, a 3.2-nm film of a CH layer was formed. At this time, nitrogen gas was introduced into the chamber, and while the gas pressure was set to 3.0 Pa in an atmosphere of mixed gas of the ethylene gas and nitrogen gas (flow ratio C₂H₄:N₂=420 sccm:350 sccm) and the bias of −400 V was applied to the substrate, a 0.3-nm film of a CHN layer was formed.

The magnetic disk was fabricated similarly to Example 1 except that the protective layer was formed as above, and the magnetic disk of Comparative Example 3 was obtained.

Subsequently, each magnetic disk of Examples and Comparative Examples was evaluated by the following test methods:

[Corrosion Resistance (Metal Ion Elution Resistance) Evaluation:

In order to evaluate corrosion resistance of the protective layer, 100 μL of nitric acid with concentration of 3% was dropped onto the surface of the magnetic disk at 8 points each, and the disk was left for approximately 1 hour. Then, the 8 points were collected and the radius of each droplet was measured and fixed at 1 mL. In these droplets, metal components were quantified by ICP (Inductively Coupled Plasma) mass analyzer, and a Co elution amount per 1 m² of the magnetic disk surface was calculated from the solution concentration and the dropped area. The smaller the eluted Co amount is, the more excellent the corrosion resistance of the protective layer is.

[Mechanical Durability Evaluation]

In order to evaluate mechanical durability of the protective layer, a pin on test was conducted. The pin on test was conducted by pressing and sliding a ball made of Al203-TiC having the diameter of 2 mm and fixed to the tip of a bar with a load of 30 g at a position of the radius of 26 mm on the magnetic disk rotating at 91.8 rpm and by measuring path counts until the protective layer was fractured. The higher the path count is, the more excellent the mechanical durability of the protective layer is. In this test, durability not less than 400 counts can be considered to be acceptable.

[Lubrication Layer Adhesion Evaluation]

The adhesion evaluation between the protective layer and the lubrication layer was made by the following test.

The lubrication layer film thickness of the magnetic disk was measured in advance by FTIR (Fourier transform infrared spectrophotometer) method. Then, the magnetic disk was immersed in a solvent (solvent used in the dip method) for 1 minute. By immersing the disk in the solvent, a lubrication layer portion with a weak adhesion force is dispersed and dissolved in the solvent, but a portion with a strong adhesion force can remain on the protective layer. The magnetic disk was pulled up from the solvent and the lubrication layer film thickness was measured by the FTIR method again. A ratio of the lubrication layer film thickness after immersion in the solvent to the lubrication layer film thickness before immersion in the solvent is referred to as a lubrication layer bonded rate. It can be said that the higher the bonded rate is, the higher the adhesion performance (adhesion) of the lubrication layer to the protective layer is.

[Head Floating Stability Evaluation]

In order to evaluate head floating stability, a magnetic disk and a magnetic recording head provided with a DFH element were mounted on a magnetic disk device, a floating amount when the magnetic recording head was floated was set to 5 nm, the environment in the magnetic disk device was set to a high-temperature and high-humidity environment at the temperature of 70° C. and the relative humidity of 80%, and a fixed-position floating test in which the magnetic recording head was made to float and run for consecutive 14 days at a specific radius position on the magnetic disk surface was conducted. In this test, if continuous running for 7 days or more is endured, the head floating stability can be considered to be acceptable.

The above evaluation results are collectively shown in the following Table 1.

TABLE 1

| | Co elution | | | |
|---|---|---|---|---|
| | amount | Pin on test | Bonded rate | Floating |
| | [μg/m²] | [path count] | [%] | stability |
| Example 1 | 0.67 | 510 | 86 | Endured for |
| | | | | consecutive |
| | | | | 14 days |
| Example 2 | 0.79 | 450 | 87 | Endured for |
| | | | | consecutive |
| | | | | 10 days |
| Example 3 | 0.57 | 480 | 84 | Endured for |
| | | | | consecutive |
| | | | | 12 days |
| Example 4 | 0.62 | 480 | 86 | Endured for |
| | | | | consecutive |
| | | | | 13 days |
| Example 5 | 0.66 | 460 | 80 | Endured for |
| | | | | consecutive 8 |
| | | | | days |
| Example 6 | 0.75 | 460 | 86 | Endured for |
| | | | | consecutive |
| | | | | 10 days |
| Comparative | 1.09 | 350 | 78 | Endured for |
| Example 1 | | | | consecutive 4 |
| | | | | days |
| Comparative | 1.12 | 450 | 80 | Endured for |
| Example 2 | | | | consecutive 6 |
| | | | | days |
| Comparative | 0.57 | 420 | 75 | Endured for |
| Example 3 | | | | consecutive 5 |
| | | | | days |

As obvious from the results in Table 1, with the magnetic disk according to the embodiments of the present invention, it was confirmed that, even if the film thickness of the protective layer is reduced to 4 nm or less, a carbon protective layer provided with corrosion resistance, mechanical durability, adhesion with the lubrication layer, and floating stability of the head can be formed.

On the other hand, with the magnetic disks in Comparative Examples 1 and 2, which contain nitrogen by exposing the CH protective layer surface formed by the CVD method to nitrogen plasma, the damage depth caused by shot of nitrogen atoms is large, and if the film thickness of the protective layer is reduced to 4 nm or less, particularly the corrosion resistance, mechanical durability, and floating stability of the head are deteriorated. Moreover, with the magnetic disk in Comparative Example 3 in which the protective layer has a lamination structure of the CH layer on the magnetic layer side and the CHN layer on the lubrication layer side formed by the CVD method, corrosion resistance or mechanical durability is not largely deteriorated, but if the film thickness of the protective layer is reduced, even if a thin film layer containing nitrogen is formed on the lubrication layer side of the protective layer, the nitridization amount on the surface of the protective layer cannot be sufficiently improved, and adhesion with the lubrication layer becomes insufficient, and floating stability of the head is deteriorated due to pickup of the lubricant and the like. In any of the magnetic disks of these Comparative Examples, the film thickness of the protective layer needs to be further increased in order to compensate for the deterioration, and reduction of the film thickness of the protective layer cannot be realized.

### REFERENCE SIGNS LIST

1 disk substrate
2 adhesion layer
3 soft magnetic layer
4 seed layer
5 underlayer
6 perpendicular magnetic recording layer
7 exchange coupling control layer
8 auxiliary recording layer
9 protective layer
10 lubrication layer
100 perpendicular magnetic recording medium

1. A manufacturing method of a magnetic recording medium in which at least a magnetic layer, a carbon protective layer, and the lubrication layer are sequentially provided on a substrate, characterized in that
said carbon protective layer is provided with a lower layer formed on said magnetic layer side and an upper layer formed on said lubrication layer side; and
said carbon protective layer is formed by forming said lower layer by a chemical vapor deposition (CVD) method by using hydrocarbon gas and by forming said upper layer by using mixed gas of hydrocarbon gas and nitrogen gas and then, by applying treatment to nitridize the surface of the upper layer.

2. The manufacturing method of a magnetic recording medium according to claim 1, wherein
the treatment of nitridizing the surface of said upper layer is performed by exposing the surface to nitrogen plasma.

3. The manufacturing method of a magnetic recording medium according to claim 1, wherein
the film thickness of said carbon protective layer is 4 nm or less.

4. The manufacturing method of a magnetic recording medium according to claim 1, wherein
a ratio in the film thickness of said lower layer to said upper layer is within a range of 9:1 to 4:1.

5. The manufacturing method of a magnetic recording medium according to claim 1, wherein
said lower layer is formed by at least two-step film formation.

6. The manufacturing method of a magnetic recording medium according to claim 5, wherein
said lower layer is formed by at least two-step film formation by changing a gas pressure in a chamber in the middle of the formation.

7. The manufacturing method of a magnetic recording medium according to claim 5, wherein
said lower layer is formed by at least two-step film formation by changing applied bias in the middle of the formation.

8. The manufacturing method of a magnetic recording medium according to claim 1, wherein
said upper layer is formed by the CVD method.

9. The manufacturing method of a magnetic recording medium according to claim 1, wherein
said lubrication layer contains a perfluoropolyether lubricant having at least three or more hydroxyl groups in one molecule.

10. The manufacturing method of a magnetic recording medium according to claim 1, wherein
said magnetic recording medium is mounted on a magnetic disk device whose start/stop mechanism is of a load-unload type and is used with a head floating amount of 5 nm or less.

11. The manufacturing method of a magnetic recording medium according to claim 10, wherein
a DFH head which thermally expands a magnetic-pole tip of a recording/reproducing element is used.

12. The manufacturing method of a magnetic recording medium according to claim 1, wherein
said magnetic recording medium is a medium for discrete track media or a medium for bit patterned media.
